(19) United States
(12) Patent Application Publication
(10) Pub. No.: US 2021/0016473 A1
(43) Pub. Date: Jan. 21, 2021

(54) IMPRINTING METHOD AND APPARATUS

(71) Applicant: KIOXIA CORPORATION, Tokyo (JP)

(72) Inventor: Hirotaka TSUDA, Yokohama Kanagawa (JP)

(21) Appl. No.: 16/805,206

(22) Filed: Feb. 28, 2020

(30) Foreign Application Priority Data
Jul. 17, 2019 (JP) 2019-132049

(51) Int. Cl. B29C 43/58

(52) U.S. Cl. CPC B29C 43/58; B29C 2043/5891; B29C 2043/5825

(57) ABSTRACT

An imprinting method includes capturing an image of a resin layer formed on a region of a first substrate with resin fluid supplied onto the first substrate from a resin fluid dispenser, determining a luminance distribution in the region in the captured image, determining a thickness distribution of the resin layer based on a relationship between a thickness of a resin layer and a luminance and the determined luminance distribution, determining a resin fluid supply condition to form a resin layer in a predetermined thickness range, based on the determined thickness distribution, and supplying resin fluid from the resin fluid dispenser onto a region of a second substrate in accordance with the determined resin fluid supply condition.

### CROSS-REFERENCE TO RELATED APPLICATION

This application is based upon and claims the benefit of priority from Japanese Patent Application No. 2019-132049, filed on Jul. 17, 2019, the entire contents of which are incorporated herein by reference.

### FIELD

Embodiments described herein relate generally to an imprinting apparatus, an imprinting method, and a semiconductor device manufacturing method.

### BACKGROUND

There is a technique of supplying liquid such as resin onto a substrate and forming a supply layer corresponding to the liquid. There is also a technique of processing the supply layer in various manners such as pattern transfer, curing through application of impulses. In such techniques, it is important to control a thickness of the supply layer formed on the substrate. However, the thickness of the supply layer may vary due to conditions for supplying a liquid onto the substrate. Thus, it is desirable to estimate a film thickness of a supply layer.

### DESCRIPTION OF THE DRAWINGS

FIG. 1 is a diagram illustrating a configuration example of an imprinting apparatus according to an embodiment.

FIG. 2 is a schematic diagram illustrating an example of a liquid droplet dropping surface of a supply section according to the embodiment.

FIGS. 3A, 3B, 3C, 3D, 3E, 3F, and 3G illustrate an example of a flow of an imprinting process according to the embodiment.

FIG. 4 is a block diagram illustrating an example of a functional configuration of a controller according to the embodiment.

FIG. 5 is a graph illustrating an example of a relationship among thickness of a resin layer and luminance according to the embodiment.

FIG. 6 is a schematic diagram illustrating an example of a captured image according to the embodiment.

FIG. 7 is a schematic diagram illustrating an example of a captured image according to the embodiment.

FIG. 8 is a diagram illustrating a specific region according to the embodiment.

FIGS. 9A and 9B illustrate difference of a thickness a resist due to adjustment of a voltage value of a drive voltage according to the embodiment.

FIGS. 10A and 10B illustrate difference of a thickness a resist due to adjustment of a frequency of a drive voltage according to the embodiment.

FIGS. 11A and 11B illustrate difference of a thickness a resist due to adjustment of a scanning speed according to the embodiment.

FIGS. 12A and 12B illustrate difference of a thickness of a resist due to adjustment of a liquid droplet dropping position according to the embodiment.

FIGS. 13A and 13B illustrate difference of a thickness of a resist due to adjustment of the number of dropped liquid droplets according to the embodiment.

FIG. 14 is a flowchart illustrating an example of a flow of an information process according to the embodiment.

FIG. 15 is a diagram illustrating a hardware configuration of the controller according to the embodiment.

### DETAILED DESCRIPTION

Embodiments provide an imprinting apparatus, an imprinting method, and a semiconductor device manufacturing method that are directed to estimating a film thickness of a supply layer formed by a liquid supplied onto a substrate.

In general, according to an embodiment, an imprinting method includes capturing an image of a resin layer formed on a region of a first substrate with resin fluid supplied onto the first substrate from a resin fluid dispenser, determining a luminance distribution in the region in the captured image, determining a thickness distribution of the resin layer based on a relationship between a thickness of a resin layer and a luminance and the determined luminance distribution, determining a resin fluid supply condition to form a resin layer in a predetermined thickness range, based on the determined thickness distribution, and supplying resin fluid from the resin fluid dispenser onto a region of a second substrate in accordance with the determined resin fluid supply condition.

Hereinafter, with reference to the accompanying drawings, an imprinting apparatus, an imprinting method, and a semiconductor device manufacturing method according to an embodiment will be described in detail. The present disclosure is not limited to the following embodiment. An element in the following embodiment includes an element that is easily conceived of by a person skilled in the art or the substantially same element.

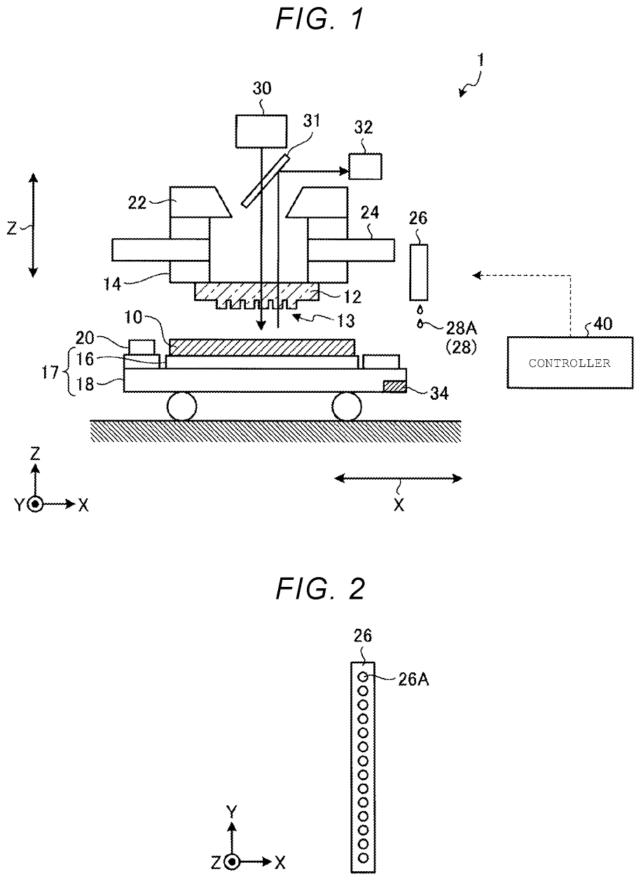

FIG. 1 is a diagram illustrating a configuration example of an imprinting apparatus 1 according to an embodiment.

The imprinting apparatus 1 includes a template 12, a template stage 14, a mounting table 17, a reference mark 20, an alignment sensor 22, a stage base 24, a supply section 26, a light source 30, a mirror 31, an imaging section 32, and a controller 40.

The mounting table 17 is provided with a wafer chuck 16 and a stage 18. The wafer chuck 16 fixes a wafer 10 as a substrate or a semiconductor substrate to a predetermined position on the stage 18. The reference mark 20 is provided on the mounting table 17. The reference mark 20 is used for alignment when the wafer 10 is loaded onto the mounting table 17.

The mounting table 17 is mounted with the wafer 10, and is moved in a plane (for example, a horizontal plane) parallel to the mounted wafer 10. The movement of the mounting table 17 is performed, for example, under driving of a drive section 34.

The drive section 34 relatively moves at least one of the mounting table 17 and the supply section 26 which will be described below in a scanning direction (that is, an arrow X direction) intersecting a direction (that is, an arrow Z direction) in which the wafer 10 mounted on the mounting table 17 faces the supply section 26. In the present embodiment, the drive section 34 moves the wafer 10 toward a lower side of the supply section 26 in a scanning direction X when the supply section 26 supplies a resist 28 (which will be described below in detail) onto the wafer 10. When a pattern is transferred onto the wafer 10, the wafer 10 is moved toward the lower side of the template 12 in the scanning direction X.

In the present embodiment, the scanning direction X matches a horizontal direction. The arrow Z direction is a vertical direction (that is, an upward-downward direction) orthogonal to the scanning direction X. An arrow Y direction is orthogonal to the scanning direction X and the arrow Z direction.

The stage base 24 supports the template 12 at the template stage 14. The stage base 24 is moved in the upward-downward direction (that is, the vertical direction or the arrow Z direction), and thus presses a pattern 13 of the template 12 against the resist 28 of the wafer 10. The alignment sensor 22 is provided on the stage base 24. The alignment sensor 22 is a sensor that detects a position of the wafer 10 or a position of the template 12.

The supply section 26 supplies the resist 28 on the wafer 10 according to an applied drive voltage. The supply section 26 may be referred to as a fluid dispenser or a resin fluid dispenser. In the present embodiment, a description will be made of an example of a case where the supply section 26 is a device that drops (in other words, ejects) a liquid droplet 28A of the resist 28 onto the wafer 10 according to an ink jet method. In this case, the supply section 26 may also be referred to as a dispenser. Hereinafter, the supply of a liquid from the supply section 26 may also be referred to as the supply of the resist 28 or dropping of the resist 28.

The supply section 26 may be a mechanism that supplies a liquid such as the resist 28 onto the wafer 10. For example, the supply section 26 may be a mechanism that applying a liquid such as the resist 28 onto the wafer 10 according to a well-known method.

FIG. 2 is a schematic diagram illustrating an example of a dropping surface for the liquid droplet 28A of the supply section 26. For example, the supply section 26 has a configuration in which a two-dimensional plane (XY plane) formed of the scanning direction X and the Y direction is assumed to be a dropping surface, and a plurality of holes 26A are arranged along the Y direction orthogonal to the scanning direction X in a plurality of arrays. The number of holes 26A and the number of arrays are not limited to the form illustrated in FIG. 2. Each of the plurality of holes 26A communicates with a liquid reservoir to which pressure is applied separately by a piezoelectric element, and ejects the liquid droplet 28A due to a pressure change in the liquid reservoir in accordance with a drive voltage applied to the piezoelectric element.

The description is continued with reference to FIG. 1 again. In the present embodiment, a description will be made of an example of a case where the supply section 26 drops the liquid droplet 28A of the resist 28.

The resist 28 is an example of a liquid supplied by the supply section 26. The resist 28 is a material onto which the pattern 13 is transferred, and may be referred to as a receiver material in some case. The resist 28 is a resin-based mask material, and may be a photocurable resin that is cured as a result of being irradiated with light or a thermosetting resin that is cured as a result of applying heat thereto. In the present embodiment, a description will be made of a case where the resist 28 is supposed to be a photocurable resin.

The light source 30 applies light with a wavelength region for curing the resist 28. The light source 30 irradiates the resist 28 with light via the template 12 in a state in which the template 12 is pressed against the resist 28 dropped on the wafer 10. The template 12 may be made of a material through which light with a wavelength region of the light source 30 and reflected light from the wafer 10 side are transmitted.

The mirror 31 transmits light applied to the wafer 10 from the light source 30 therethrough, and reflects observation light from the wafer 10 and a supply layer (which will be described below in detail) formed by the resist 28 dropped on the wafer 10. The mirror 31 is, for example, a dichroic mirror.

The imaging section 32 images a supply layer formed by the resist 28 that is a liquid supplied onto the wafer 10, and thus obtains a captured image of the supply layer. Specifically, observation light from the supply layer on the wafer 10 is transmitted through the template 12 to be reflected at the mirror 31, and then reaches the imaging section 32. Thus, the imaging section 32 images the supply layer on the wafer 10 via the mirror 31 and the template 12, and thus obtains the captured image.

The imaging section 32 is a well-known imaging device that obtains captured image data through imaging. In the present embodiment, the captured image data will be simply referred to as a captured image.

The controller 40 is coupled to each element of the imprinting apparatus 1 and controls each element. Specifically, the controller 40 is electrically coupled to each of a drive section (not illustrated) of the template stage 14, the drive section 34 of the mounting table 17, the supply section 26, the light source 30, and the imaging section 32, and controls each of the elements. The controller 40 may be referred to as a control circuit.

Each of the elements is controlled by the controller 40, and thus an imprinting process and semiconductor device manufacturing are performed.

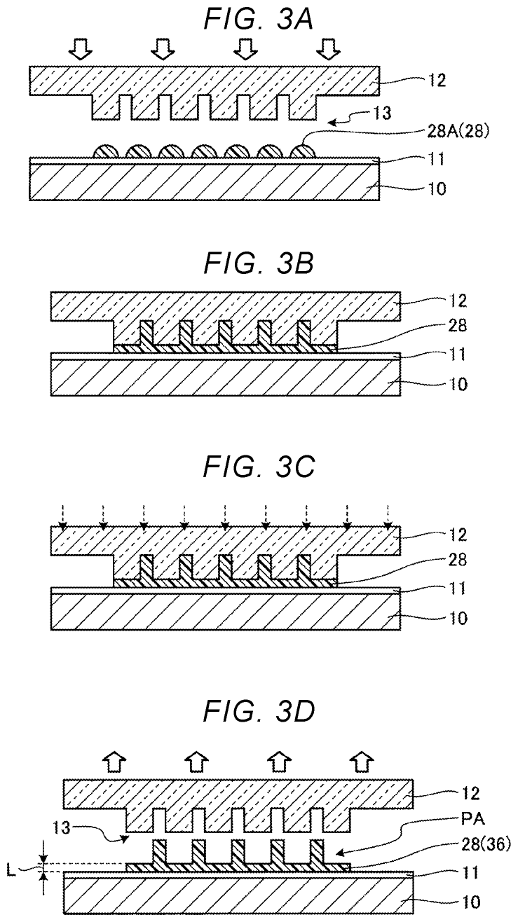

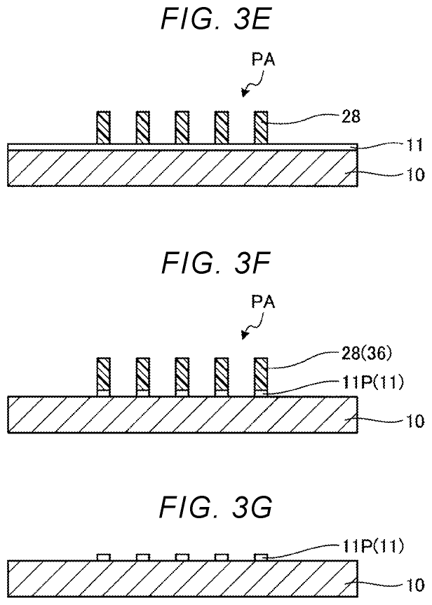

FIGS. 3A to 3G are diagrams illustrating an example of a flow of an imprinting process. The imprinting process is included in a semiconductor device manufacturing process.

First, a treatment film 11 is formed on the wafer 10. The treatment film 11 may be formed according to a well-known method. The wafer 10 on which the treatment film 11 is formed is mounted on the mounting table 17, and the mounting table 17 is moved to the lower side of the supply section 26. The wafer 10 on which the treatment film 11 is not formed may be mounted on the mounting table 17.

The controller 40 applies a drive voltage to the supply section 26, and thus the liquid droplet 28A is dropped onto the treatment film 11 of the wafer 10 from the supply section 26 (refer to FIG. 3A). Due to the step, the liquid droplet 28A of the resist 28 that is an example of a transfer manufacturer is dropped onto the treatment film 11 formed on the wafer 10 that is an example of a semiconductor substrate.

In this case, the controller 40 performs control of adjusting at least one of a voltage value of a drive voltage supplied to the supply section 26, a frequency of the drive voltage, a dropping position of the liquid droplet 28A, and the number of dropped liquid droplets 28A. Due to the adjustment, at least one of an amount of each dropped liquid droplet 28A, an amount of the liquid droplets 28A per unit area on the wafer 10, a dropping position on the wafer 10, and the number of droplets on the wafer 10 is adjusted. A dropping position and the number of droplets on the wafer 10 are defined in, for example, dropping data for defining a dropping position coordinate. The dropping data will also be referred to as a drop recipe. The controller 40 controls the supply section 26 to eject the liquid droplet 28A at a dropping position and the number of droplets defined in the dropping data, and thus the supply section 26 drops the liquid droplet 28A at the dropping position and the number of droplets defined in the dropping data.

In this case, the controller 40 controls the drive section 34, and thus a movement speed of the mounting table (that is, the wafer 10) in the scanning direction X. When the liquid droplet 28A is dropped onto the wafer 10, a movement speed of the wafer 10 in the scanning direction X is controlled, and thus a dropping interval of the liquid droplet 28A in the scanning direction X is controlled.

The controller 40 controls the drive section 34 to move the mounting table 17 to the lower side of the template 12.

As illustrated in FIG. 3B, the controller 40 controls the drive section (not illustrated) to move the template stage 14 in a direction (that is, a downward direction) coming close to the mounting table 17. In this case, the controller 40 performs alignment by using the alignment sensor 22, and performs control such that the pattern 13 formed on the template 12 is pressed against the resist 28.

When this state is maintained for a predetermined time, the liquid resist 28 (that is, the liquid droplet 28A) spreads between the template 12 and the wafer 10, and thus fills a recess portion of the pattern 13 of the template 12.

Next, as illustrated in FIG. 3C, the light source 30 irradiates the resist 28 with light in a state in which the template 12 is pressed, and thus the resist 28 is cured. For example, the controller 40 performs control of lighting the light source 30 such that the resist 28 is irradiated with light, and thus the resist 28 is cured.

Next, as illustrated in FIG. 3D, the template 12 is peeled off. Consequently, a transfer region PA to which the pattern 13 of the template 12 is transferred is formed on the treatment film 11 of the wafer 10. The transfer region PA is formed by the resist 28, and is a region to which the pattern 13 is transferred. In other words, through this process, a supply layer 36 formed by the resist 28 to which the pattern 13 is transferred is in a state of being formed on the wafer 10.

The pattern 13 formed on the template 12 is transferred onto the resist 28 that is an example of a receiver material on the wafer 10 through the steps in FIGS. 3B to 3D. The imprinting process is implemented through the steps in FIGS. 3A to 3D.

In order to perform a semiconductor device manufacturing process, the following steps are executed (refer to FIGS. 3E to 3G) in addition to the imprinting process.

For example, the recess portion in the transfer region PA is removed through etching (refer to FIG. 3E), and the treatment film 11 is treated with the transfer region PA as a mask (refer to FIG. 3F). Consequently, a pattern 11P of the treatment film 11 corresponding to the pattern 13 is formed. The resist 28 is peeled off through asking or the like, and thus the pattern 11P of the treatment film 11 formed on the wafer 10 is obtained (refer to FIG. 3G). The process is repeatedly performed such that patterns 11P of a plurality of treatment films 11 are stacked and formed on the wafer 10, and thus a semiconductor device is manufactured.

Here, it is considerably important to control a film thickness of the supply layer 36 formed by the resist 28 ejected onto the wafer 10. For example, in a case of a fine pattern in which an uneven portion of the pattern 13 is in a range from several tens of nm to 100 nm, it is important to control a total amount of the resist 28 supplied onto the wafer 10.

When the inkjet supply section 26 is used as the supply section 26, a required sufficient amount of the resist 28 may be supplied onto the wafer 10 by taking into consideration a coating ratio of the fine pattern 13 of the template 12 or a dropping directivity. However, even when the inkjet supply section 26 is used, a thickness of the supply layer 36 may change due to factors such as drive waveform interference between the liquid reservoirs communicating with the holes 26A during dropping, deterioration over time, and an environmental change.

Specifically, for example, it is assumed that a supply condition for the supply section 26 is constant such that a desired dropping amount of the liquid droplet 28A is dropped from the holes 26A of the supply section 26. However, an actual amount of the dropped liquid droplet 28A may change due to an environmental change such as temperature and humidity, clogging of the hole 26A, and a status change of the imprinting apparatus 1 during startup or shutdown of the imprinting apparatus 1.

As the number of holes 26A simultaneously ejecting the liquid droplets 28A becomes larger, an amount of the liquid droplet 28A ejected from a single hole 26A may be reduced even when an identical drive voltage is applied. For example, as a gap (that is, a gap in the Y direction; refer to FIG. 2) between the holes 26A ejecting the liquid droplets 28A at an identical timing becomes smaller, an amount of the liquid droplet 28A ejected from the single hole 26A may be reduced.

Thus, there is a case where a thickness of the supply layer 36 may be non-uniform, and thus a technique of easily estimating a thickness of the supply layer 36 is desirable.

Therefore, in the imprinting apparatus 1 of the present embodiment, the controller 40 calculates a film thickness of the supply layer 36 (e.g., thickness distribution) by using a captured image of the supply layer 36.

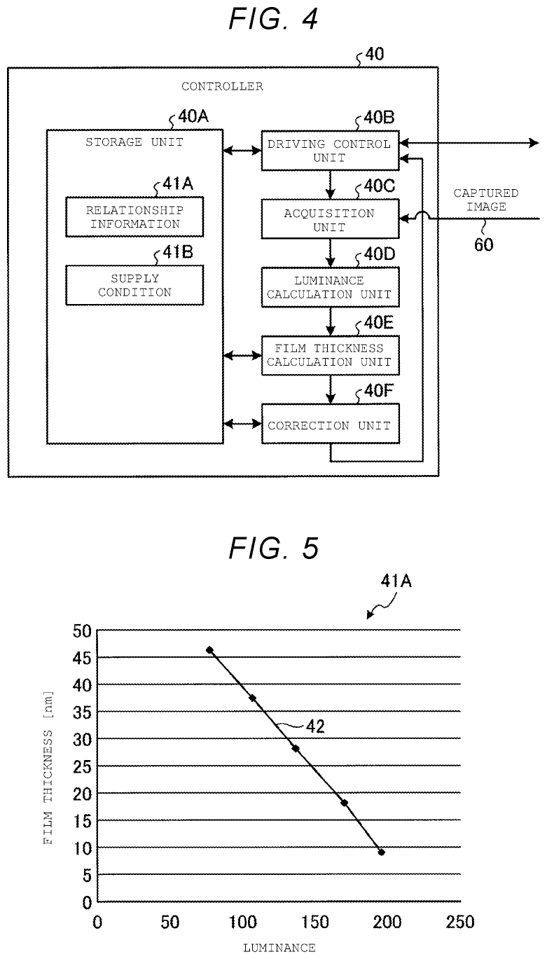

FIG. 4 is a block diagram illustrating an example of a functional configuration of the controller 40. The controller 40 includes a storage unit 40A, a driving control unit 40B, an acquisition unit 40C, a luminance calculation unit 40D, a film thickness calculation unit 40E, and a correction unit 40F.

The driving control unit 40B, the acquisition unit 40C, the luminance calculation unit 40D, the film thickness calculation unit 40E, and the correction unit 40F are realized by one or a plurality of processors. For example, each of the units may be implemented by a processor such as a central processing unit (CPU) executing a program or by software. Each of the units may be implemented by a processor such as a dedicated integrated circuit (IC), that is, hardware. Each of the units may be implemented through combined use of software and hardware. When a plurality of processors are used, each processor may implement one of the respective units, and may implement two or more of the respective units.

The storage unit 40A stores various pieces of data. In the present embodiment, the storage unit 40A stores relationship information 41A and supply condition 41B.

The relationship information 41A is information indicating a relationship between a film thickness and the luminance.

The film thickness indicated in the relationship information 41A indicates a thickness of the supply layer 36. The thickness of the supply layer 36 is a thickness of the transfer region PA of the resist 28 to which the pattern 13 of the template 12 is pressed against the liquid droplet 28A dropped on the wafer 10 to be transferred. The thickness of the transfer region PA may be a thickness of the transfer region PA after being cured due to irradiation with light from the light source 30, and may be a thickness of the transfer region PA before being cured.

In the present embodiment, a description will be made of an example of a case where the thickness of the supply layer 36 is a thickness of the transfer region PA after being cured or solidified.

The thickness of the supply layer 36 may be any one of an average thickness of the transfer region PA to which the uneven pattern 13 is transferred, a thickness of a recess portion, and a thickness of a protrusion portion in the supply layer 36. In the present embodiment, a description will be made of an example of a case where the thickness of the supply layer 36 is a thickness (refer to a thickness L in FIG. 3D) of the recess portion of the transfer region PA.

The luminance indicated in the relationship information 41A indicates the luminance of the transfer region PA of the supply layer 36. The luminance of the transfer region PA may be average luminance of the whole transfer region PA, and average luminance of a specific region in the transfer region PA. The specific region may be a region set at a predefined location and having predefined size and range in the transfer region PA. For example, the specific region is preferably a region corresponding to a plurality of pixels (for example, two or more pixels). In the present embodiment, a description will be made of an example of a case where the luminance of the transfer region PA is average luminance of a specific region in the transfer region PA (that is, a region to which the pattern 13 is transferred) after being cured or solidified.

FIG. 5 is a diagram illustrating an example of the relationship information 41A. In FIG. 5, a longitudinal axis expresses a film thickness of the supply layer 36, and a transverse axis expresses the luminance of the transfer region PA of the supply layer 36.

As illustrated in FIG. 5, for example, a relationship between luminance and a film thickness is represented by a line diagram 42. A relationship between luminance and a film thickness is not limited to a relationship represented by a straight line indicating a linear function as illustrated in FIG. 5.

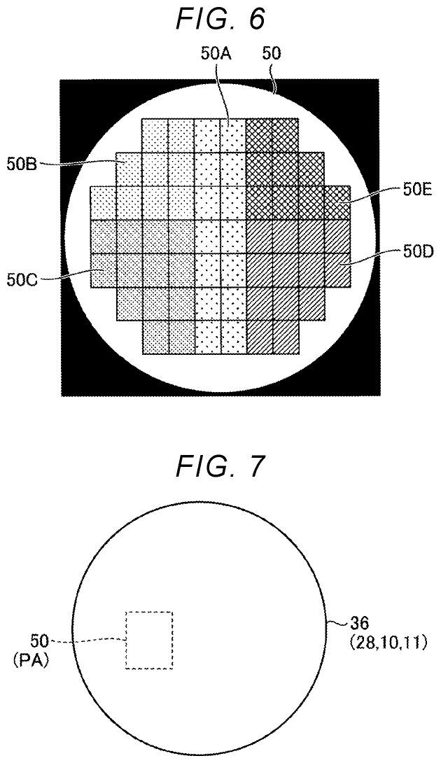

FIG. 6 is a schematic diagram illustrating an example of a captured image 50. The captured image 50 is an example of a captured image obtained by the imaging section 32 with respect to a plurality of subregions (for example, a subregion 50A to a subregion 50E) in which thicknesses of the resist 28 are different from each other. The subregion 50A is a region with a thickness of 10 nm, and the subregion 50B is a region with a thickness of 20 nm. The subregion 50C is a region with a thickness of 30 nm, and the subregion 50D is a region with a thickness of 40 nm. The subregion 50E is a region with a thickness of 50 nm. As illustrated in FIG. 6, the luminance differs depending on a thickness of the resist 28. Thus, there will be a luminance distribution corresponding to a thickness distribution of the resist 28.

In the imprinting apparatus 1, a relationship between a film thickness of the supply layer 36 and the luminance of the transfer region PA of the supply layer 36 may be measured in advance, to be stored in advance in the storage unit 40A as the relationship information 41A. The film thickness defined in the relationship information 41A may be derived, for example, by actually measuring a thickness of the transfer region PA of the supply layer 36. The luminance defined in the relationship information 41A may be derived, for example, by calculating the luminance of a captured image of the transfer region PA of the supply layer 36 formed on the wafer 10 according to a well-known method.

The description will be continued referring to FIG. 4 again. Details of the supply condition 41B will be described below.

The driving control unit 40B is coupled to each element of the imprinting apparatus 1 and controls each element. The driving control unit 40B controls each of the drive section (not illustrated) of the template stage 14, the drive section 34 of the mounting table 17, the supply section 26, the light source 30, and the imaging section 32 such that the imprinting process or the semiconductor device manufacturing process is executed.

The driving control unit 40B controls the supply section 26 and the drive section 34 when the resist 28 is dropped onto the wafer 10.

Specifically, the driving control unit 40B controls the supply section 26 and the drive section 34 based on the supply condition 41B.

The supply condition 41B is information indicating control conditions for each of the elements when the resist 28 is dropped onto the wafer 10. The supply condition 41B includes at least one of, for example, a voltage value of a drive voltage applied to the supply section 26, a frequency of the drive voltage, a scanning speed (movement speed) of the mounting table 17 mounted with the wafer 10, a dropping position (that is, a supply position) of the liquid droplet 28A on the wafer 10, and the number of dropped liquid droplets 28A (that is, the number of supplied liquid droplets 28A) per unit area.

The driving control unit 40B controls the elements based on the supply condition 41B, and thus the liquid droplet 28A is dropped onto the wafer 10 from each of the plurality of holes 26A of the supply section 26.

The acquisition unit 40C acquires the captured image 50 from the imaging section 32. The captured image 50 is captured image data obtained by imaging the supply layer 36. For example, the driving control unit 40B controls the imaging section 32 to image the transfer region PA of the supply layer 36 formed by the resist 28 to which the pattern 13 of the template 12 is transferred and which is cured by light applied from the light source 30. The driving control unit 40B may control the imaging section 32 to image at least the transfer region PA of the supply layer 36 when the supply layer 36 to which the pattern 13 is transferred and which is the cured resist 28 is in a state of being formed on the wafer 10 (refer to FIG. 3D). The acquisition unit 40C may acquire the captured image 50 of the transfer region PA from the imaging section 32.

FIG. 7 is a schematic diagram illustrating an example of the captured image 50 acquired by the acquisition unit 40C. The captured image 50 is a captured image of at least the transfer region PA of the supply layer 36 formed by curing the resist 28 which is dropped on the wafer 10 and to which the pattern 13 is transferred.

The description will be continued referring to FIG. 4 again. The luminance calculation unit 40D calculates the luminance of the captured image 50. In the present embodiment, the luminance calculation unit 40D calculates the luminance of the transfer region PA of the captured image 50. As described above, in the present embodiment, a description will be made of an example of a case where the luminance of the transfer region PA is average luminance of a specific region in the transfer region PA.

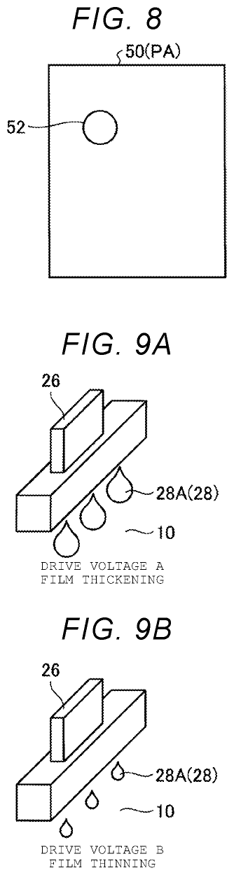

FIG. 8 is a diagram illustrating a specific region 52. The specific region 52 may be a specific region in the transfer region PA of the captured image 50. As described above, the specific region 52 is preferably a region including two or more pixels. A position, a size, and a range of the supply layer 36 formed on the wafer 10, corresponding to the specific region 52 in the captured image 50 are the same as a position, a size, and a range used to drive the relationship information 41A used for a process which will be described below.

The description will be continued referring to FIG. 4 again. The luminance calculation unit 40D may calculate the luminance of the specific region 52 in the transfer region PA of the captured image 50 by using a well-known image processing technique. Specifically, the luminance calculation unit 40D may calculate an average value of the luminance of each of a plurality of pixels forming the specific region 52 as the luminance of the specific region 52.

In the above-described way, the luminance calculation unit 40D calculates the luminance of the specific region 52 in the transfer region PA of the pattern 13, that is, a region obtained by imaging the uneven portion of the pattern 13, in the captured image 50.

The film thickness calculation unit 40E calculates a film thickness of the supply layer 36 based on the relationship information 41A. The film thickness calculation unit 40E calculates the film thickness of the supply layer 36 by specifying a film thickness corresponding to the luminance calculated by the luminance calculation unit 40D from the relationship information 41A.

The correction unit 40F corrects the supply condition 41B such that the film thickness calculated by the film thickness calculation unit 40E becomes a desired film thickness.

The desired film thickness is information indicating a desired film thickness of the specific region 52. The desired film thickness may be set in advance. The desired film thickness may be changeable as appropriate through a user's operation input on an input section such as a keyboard.

The correction unit 40F determines whether or not the film thickness calculated by the film thickness calculation unit 40E matches the desired film thickness. The correction unit 40F may determine that the thicknesses match each other when one of the calculated film thickness and the desired film thickness has a value within a preset range (for example, within a range of ±10%) with respect to the other thereof.

When it is determined that the film thickness calculated by the film thickness calculation unit 40E matches the desired film thickness, the correction unit 40F does not correct the supply condition 41B. On the other hand, when it is determined that the film thickness calculated by the film thickness calculation unit 40E does not match the desired film thickness (that is, the calculated film thickness is different from the desired film thickness), the correction unit 40F corrects the supply condition 41B such that the film thickness of the supply layer 36 matches the desired film thickness.

Specifically, when the film thickness calculated by the film thickness calculation unit 40E is smaller than the desired film thickness, the correction unit 40F corrects the supply condition 41B such that a thickness of the resist 28 formed by the liquid droplet 28A ejected from the supply section 26 is larger than the current thickness. Specifically, the correction unit 40F corrects the supply condition 41B such that at least one of an amount of each liquid droplet 28A ejected from the supply section 26, the number of dropped liquid droplets 28A per unit area on the wafer 10, and a density of dropped liquid droplets 28A on the wafer 10 is increased compared with the current state.

On the other hand, when the film thickness calculated by the film thickness calculation unit 40E is larger than the desired film thickness, the correction unit 40F corrects the supply condition 41B such that a thickness of the resist 28 formed by the liquid droplet 28A ejected from the supply section 26 is smaller than the current thickness. Specifically, the correction unit 40F corrects the supply condition 41B such that at least one of an amount of each liquid droplet 28A ejected from the supply section 26, the number of dropped liquid droplets 28A per unit area on the wafer 10, and a density of dropped liquid droplets 28A on the wafer 10 is decreased compared with the current state.

FIGS. 9A and 9B are diagrams illustrating difference of a thickness of the resist 28 due to adjustment of a voltage value of a drive voltage applied to the supply section 26. FIG. 9A is a diagram illustrating the liquid droplet 28A ejected when a drive voltage with a drive voltage value A is applied to the piezoelectric element of the supply section 26. FIG. 9B is a diagram illustrating the liquid droplet 28A ejected when a drive voltage with a drive voltage value B is applied to the piezoelectric element of the supply section 26. The drive voltage value A is greater than the drive voltage value B.

As illustrated in FIGS. 9A and 9B, as a voltage value of the drive voltage becomes greater, an amount of the liquid droplet 28A ejected from the hole 26A of the supply section 26 becomes larger, and thus the resist 28 is thickened. On the other hand, as a voltage value of the drive voltage becomes smaller, an amount of the liquid droplet 28A ejected from the hole 26A of the supply section 26 becomes smaller, and thus the resist 28 is thinned. Thus, the supply layer 36 is thickened or thinned by adjusting a voltage value of a drive voltage applied to the supply section 26.

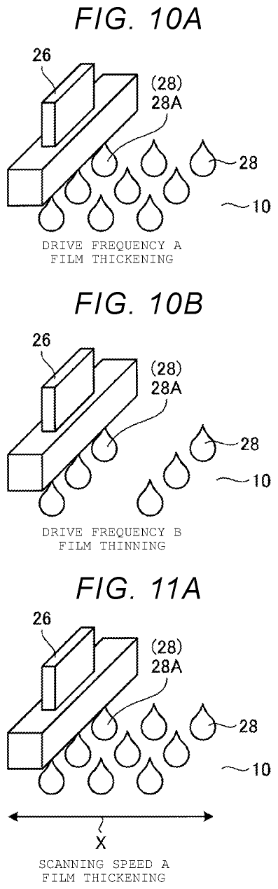

FIGS. 10A and 10B are diagrams illustrating difference of a thickness of the resist 28 due to adjustment of a frequency of a drive voltage applied to the supply section 26. FIG. 10A is a diagram illustrating the liquid droplet 28A ejected when a drive voltage with a drive frequency A is applied to the piezoelectric element of the supply section 26. FIG. 10B is a diagram illustrating the liquid droplet 28A ejected when a drive voltage with a drive frequency B is applied to the piezoelectric element of the supply section 26. The drive frequency A is higher than the drive frequency B.

As illustrated in FIGS. 10A and 10B, as a drive frequency of the drive voltage applied to the supply section becomes higher, an ejection interval of the liquid droplet 28A ejected from the hole 26A of the supply section 26 is reduced, and thus the resist 28 is thickened. On the other hand, as a drive frequency of the drive voltage applied to the supply section 26 becomes lower, an ejection interval of the liquid droplet 28A ejected from the hole 26A of the supply section 26 is increased, and thus the resist 28 is thinned. Thus, the supply layer 36 is thickened or thinned by adjusting a frequency of a drive voltage applied to the supply section 26.

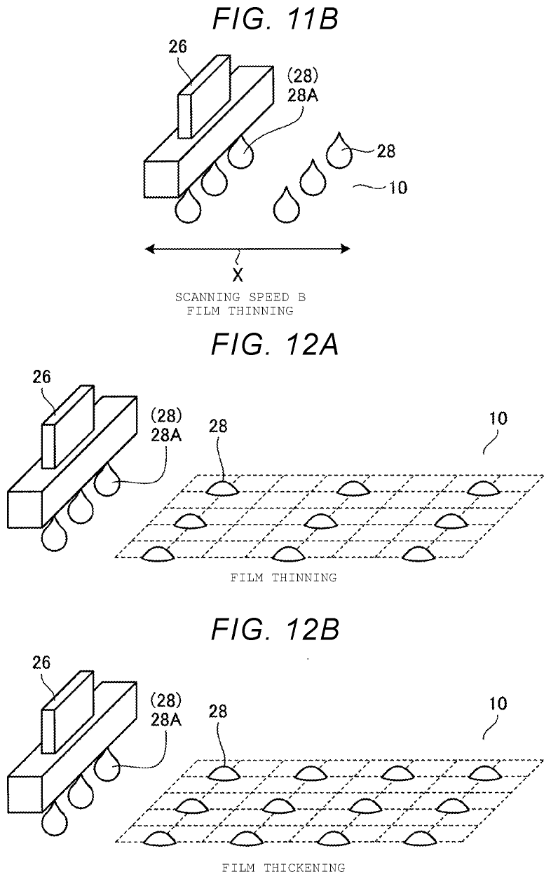

FIGS. 11A and 11B are diagrams illustrating difference of a thickness of the resist 28 due to adjustment of a scanning speed of the wafer 10 (that is, the mounting table 17) in the scanning direction X. FIG. 11A is a diagram illustrating a case where the wafer 10 is scanned in the scanning direction X at a scanning speed A during dropping of the liquid droplet 28A onto the wafer 10. FIG. 11B is a diagram illustrating a case where the wafer 10 is scanned in the scanning direction X at a scanning speed B during dropping of the liquid droplet 28A onto the wafer 10. The scanning speed A is lower than the scanning speed B.

As illustrated in FIGS. 11A and 11B, as a scanning speed becomes lower, an interval of the liquid droplets 28A (that is, the resist 28) dropped on the wafer 10 in the scanning direction X is reduced, and thus the resist 28 is thickened. On the other hand, as a scanning speed becomes higher, an interval of the liquid droplets 28A (that is, the resist 28) dropped on the wafer 10 in the scanning direction X is increased, and thus the resist 28 is thinned.

Thus, the resist 28 is thickened or thinned by adjusting a relative movement speed (that is, a scanning speed) between the wafer 10 and the supply section 26 in the scanning direction X.

FIGS. 12A and 12B are diagrams illustrating difference of a thickness of the resist 28 due to adjustment of a dropping position of the liquid droplet 28A on the wafer 10. FIG. 12A is a diagram illustrating a case where a dropping position of the liquid droplet 28A on the wafer 10 is adjusted such that a density of the dropped liquid droplet 28A per unit area is low. FIG. 12B is a diagram illustrating a case where a dropping position of the liquid droplet 28A on the wafer 10 is adjusted such that a density of the dropped liquid droplet 28A per unit area is high.

As illustrated in FIG. 12A, as dropping positions of the adjacent liquid droplets 28A are separated from each other on the wafer 10, a density of the liquid droplet 28A per unit area becomes lower, and thus the resist 28 is thinned. On the other hand, as illustrated in FIG. 12B, as dropping positions of the adjacent liquid droplets 28A come close each other on the wafer 10, a density of the liquid droplet 28A per unit area becomes higher, and thus the resist 28 is thickened.

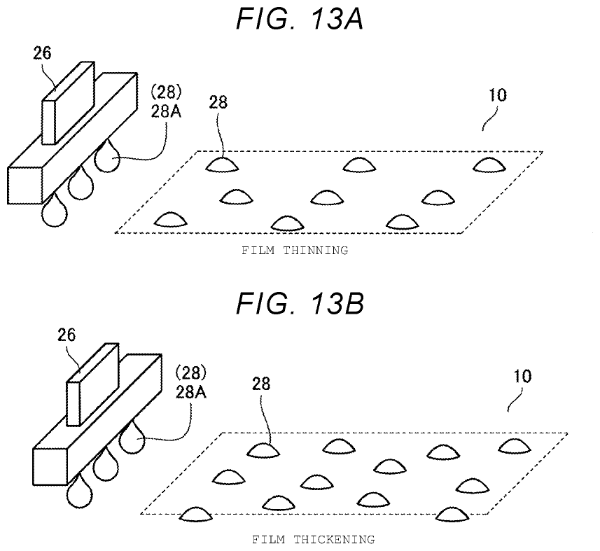

FIGS. 13A and 13B are diagrams illustrating difference of a thickness of the resist 28 due to adjustment of the number of the liquid droplets 28A dropped onto the wafer 10. FIG. 13A is a diagram illustrating a case where the number of the liquid droplets 28A dropped onto the wafer 10 is adjusted such that a density of the dropped liquid droplet 28A per unit area is low. FIG. 13B is a diagram illustrating a case where the number of the liquid droplets 28A dropped onto the wafer 10 is adjusted such that a density of the dropped liquid droplet 28A per unit area is high.

As illustrated in FIG. 13A, as the number of the liquid droplets 28A dropped onto the wafer 10 becomes smaller, a density of the liquid droplet 28A per unit area becomes lower, and thus the resist 28 is thinned. On the other hand, as illustrated in FIG. 13B, as the number of the liquid droplets 28A dropped onto the wafer 10 becomes larger, a density of the liquid droplet 28A per unit area becomes higher, and thus the resist 28 is thickened.

The description will be continued referring to FIG. 4 again. Thus, the correction unit 40F corrects the supply condition 41B corresponding to at least one of a voltage value of a drive voltage, a frequency of the drive voltage, a relative movement speed of at least one of the wafer 10 and the supply section 26 in the scanning direction X, a supply position of the liquid droplet 28A on the wafer 10, and the number of liquid droplets 28A supplied to the wafer 10 per unit area such that the film thickness calculated by the film thickness calculation unit 40E matches the desired film thickness.

In other words, the correction unit 40F changes and updates the supply condition 41B stored in the storage unit 40A such that the supply condition 41B after being corrected are obtained.

Thus, the driving control unit 40B controls the supply section 26 and the drive section 34 according to the supply condition 41B stored in the storage unit 40A, and can thus execute measurement of a film thickness of the supply layer 36 and control for matching the film thickness of the supply layer 36 with a desired film thickness during the imprinting process or the semiconductor device manufacturing process.

Next, a description will be made of an example of a flow of information processing executed by the controller 40.

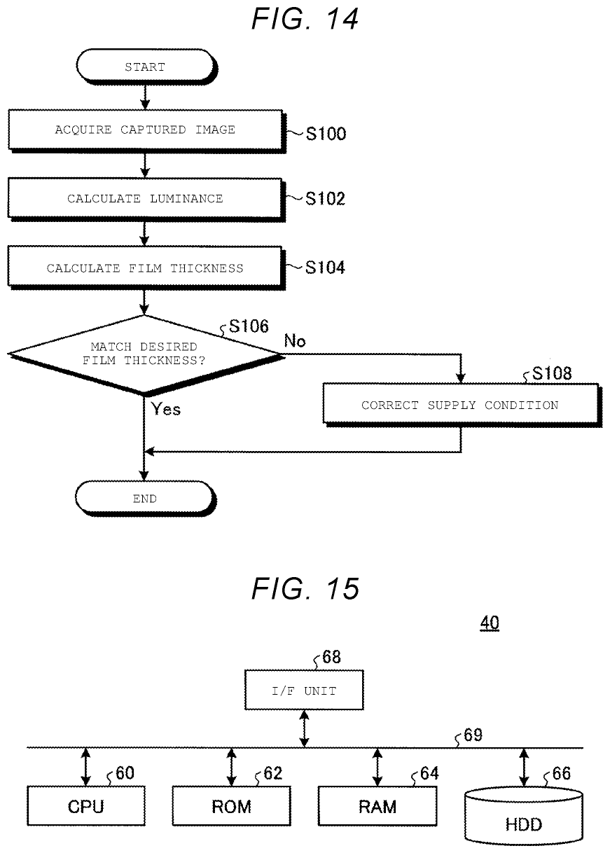

FIG. 14 is a flowchart illustrating an example of a flow of information processing executed by the controller 40 of the present embodiment. The driving control unit 40B of the controller 40 executes the imprinting process or the semiconductor device manufacturing process. The controller executes a process illustrated in FIG. 14 for each predefined timing. The predefined timing is, for example, each imprinting process executed by the imprinting apparatus 1 or each wafer 10, but is not limited thereto.

The acquisition unit 40C acquires the captured image 50 of the transfer region PA of the supply layer 36 from the imaging section 32 (step S100).

The luminance calculation unit 40D calculates the luminance of the captured image 50 acquired in step S100 (step S102). As described above, in the present embodiment, the luminance calculation unit 40D calculates the luminance of the specific region 52 in the transfer region PA in the captured image 50.

The film thickness calculation unit 40E calculates a film thickness of the supply layer 36 based on the luminance calculated in step S102 (step S104). The film thickness calculation unit 40E calculates the film thickness of the supply layer 36 by acquiring a film thickness corresponding to the luminance calculated in step S102 from the relationship information 41A.

Next, the correction unit 40F determines whether or not the film thickness calculated in step S104 matches a desired film thickness (step S106). When it is determined that the film thickness calculated in step S104 matches the desired film thickness (step S106: Yes), the present routine is finished.

On the other hand, when it is determined that the film thickness calculated in step S104 does not match the desired film thickness (step S106: No), the flow proceeds to step S108.

In step S108, the correction unit 40F corrects the supply condition 41B such that the film thickness calculated in step S104 matches the desired film thickness (step S108). Through the process in step S108, the driving control unit 40B controls the supply section 26 and the drive section 34 according to the supply condition 41B after being corrected, and thus executes measurement of a film thickness of the supply layer 36 and control for matching the film thickness of the supply layer 36 with the desired film thickness during the imprinting process or the semiconductor device manufacturing process. The present routine is finished.

The correction process for the supply condition 41B in step S108 is applied to the following case.

Specifically, when the process illustrated in FIG. 14 is executed for each imprinting process in the imprinting apparatus 1, a single imprinting process is performed on one partition (that is, a shot region) on the wafer 10 to form the supply layer 36, and the correction process for the supply condition 41B in step S108 is applied in a case of another shot region on the identical wafer 10.

When the process illustrated in FIG. 14 is executed for each wafer 10, the imprinting process is executed on a plurality of shot regions on the wafer 10, and the correction process for the supply condition 41B in step S108 is applied in a case of the next wafer 10.

As described above, the imprinting apparatus 1 of the present embodiment includes the acquisition unit 40C, the luminance calculation unit 40D, and the film thickness calculation unit 40E. The acquisition unit 40C acquires the captured image 50 of the supply layer 36 formed by a liquid (that is, the resist 28) supplied onto a substrate (that is, the wafer 10). The luminance calculation unit 40D calculates the luminance of the captured image 50. The film thickness calculation unit 40E calculates a film thickness of the supply layer 36 based on the relationship information 41A indicating a relationship between a film thickness and luminance, and the calculated the luminance.

As mentioned above, the imprinting apparatus 1 of the present embodiment calculates a film thickness of the supply layer 36 based on the luminance of the captured image 50.

Thus, it is possible to easily calculate a film thickness of the supply layer 36 without actually measuring the film thickness of the supply layer 36 formed on the wafer 10.

Therefore, the imprinting apparatus 1 of the present embodiment can easily estimate a film thickness of the supply layer 36 formed by the resist 28 (that is, a liquid) supplied onto the wafer 10 (that is, a substrate).

The imprinting apparatus 1 of the present embodiment corrects the supply condition 41B for a liquid (that is, the resist 28) onto the wafer 10 such that a calculated film thickness matches a desired film thickness.

Thus, the supply section 26 and the drive section 34 are controlled based on the corrected supply condition 41B, and thus a supply condition for the resist 28 can be easily adjusted such that a film thickness of the supply layer 36 matches a desired film thickness.

The relationship information 41A may indicate different relationships depending on imaging conditions for the supply layer 36. For example, the luminance of the transfer region PA of the supply layer 36 may differ depending on the type or a structure of a layer (for example, the wafer 10 or the treatment film 11) present in a lower layer of the supply layer 36 during imaging of the supply layer 36. The luminance of the transfer region PA of the supply layer 36 may change depending on a wavelength of light applied during imaging of the transfer region PA, or the type of a light source that applies light when the light is applied during imaging.

Therefore, in the imprinting apparatus 1, the relationship information 41A corresponding to an imaging condition may be measured in advance for each imaging condition for the supply layer 36, to be stored in the storage unit 40A in advance in correlation with the imaging condition.

In this case, the film thickness calculation unit 40E may read the relationship information 41A corresponding to the imaging condition related to the captured image 50 acquired by the acquisition unit 40C from the storage unit 40A, and may calculate a film thickness of the supply layer 36 based on the read relationship information 41A in the same manner as described above.

Next, a description will be made of an example of a hardware configuration of the controller 40 provided in the imprinting apparatus 1.

FIG. 15 is a diagram illustrating an example of a hardware configuration of the controller 40 of the embodiment.

The controller 40 of the embodiment includes a CPU 60, storage devices such as a read only memory (ROM) 62, a random access memory (RAM) 64, and a hard disk drive (HDD) 66, an I/F unit 68 that is an interface with various apparatuses, and a bus 69 connecting the respective elements to each other, and has a hardware configuration using a typical computer.

In the controller 40 of the embodiment, the CPU 60 reads a program from the ROM 62 to the RAM 64, and executes the program, and thus the units are implemented on the computer.

A program for executing each process executed by the controller 40 of the embodiment may be stored in the HDD 66. The program for executing each process executed by the controller 40 of the embodiment may be incorporated into the ROM 62 to be provided.

The program for executing each process executed by the controller 40 of the embodiment may be stored on a computer readable storage medium such as a CD-ROM, a CD-R, a memory card, a digital versatile disk (DVD), or a flexible disk (FD) in a file with an installable form or an executable form, to be provided as a computer program product. The program for executing each process executed by the controller 40 of the embodiment may be stored on a computer coupled to a network such as the Internet, and may be downloaded via the network to be provided. The program for executing each process executed by the controller 40 of the embodiment may be provided or distributed via a network such as the Internet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprinting method comprising:
capturing an image of a resin layer formed on a region of a first substrate with resin fluid supplied onto the first substrate from a resin fluid dispenser;
determining a luminance distribution in the region in the captured image;
determining a thickness distribution of the resin layer based on a relationship between a thickness of a resin layer and a luminance and the determined luminance distribution;
determining a resin fluid supply condition to form a resin layer in a predetermined thickness range, based on the determined thickness distribution; and
supplying resin fluid from the resin fluid dispenser onto a region of a second substrate in accordance with the determined resin fluid supply condition.

2. The imprinting method according to claim 1, wherein the thickness distribution indicates a first subregion in the region of the first substrate having a first thickness and a second subregion in the region of the first substrate having a second thickness greater than the first thickness.

3. The imprinting method according to claim 2, wherein the resin fluid supply condition includes a first drive voltage to be applied to the resin fluid dispenser when supplying the resin fluid onto a subregion corresponding to the first subregion and a second drive voltage to be applied to the resin fluid dispenser when supplying the resin fluid onto a subregion corresponding to the second subregion, the second drive voltage being greater than the first drive voltage.

4. The imprinting method according to claim 2, wherein the resin fluid supply condition includes a first frequency of a first drive voltage to be applied to the resin fluid dispenser when supplying the resin fluid onto a subregion corresponding to the first subregion and a second frequency of a second drive voltage to be applied to the resin fluid dispenser when supplying the resin fluid onto a subregion corresponding to the second subregion, the second frequency being greater than the first frequency.

5. The imprinting method according to claim 2, wherein the resin fluid supply condition includes a first speed of movement of the resin fluid dispenser when supplying the resin fluid onto a subregion corresponding to the first subregion and a second speed of the movement of the resin fluid dispenser when supplying the resin fluid onto a subregion corresponding to the second subregion, the second speed being less than the first speed, the movement of the resin fluid dispenser being along a substrate surface.

6. The imprinting method according to claim 2, wherein the resin fluid supply condition includes a first amount of fluid resin supply per unit area when supplying the resin fluid onto a subregion corresponding to the first subregion and a second amount of fluid resin supply per the unit area when supplying the resin fluid onto a subregion corresponding to the second subregion, the second amount being greater than the first amount.

7. The imprinting method according to claim 2, wherein the resin fluid supply condition includes a first fluid resin drop location when supplying the resin fluid onto a subregion corresponding to the first subregion and a second fluid resin drop location when supplying the resin fluid onto a subregion corresponding to the second subregion.

8. The imprinting method according to claim 1, wherein the resin layer formed on the region of the first substrate is a solidified resin layer.

9. The imprinting method according to claim 1, wherein the relationship includes a first relationship between a thickness of a resin layer and a luminance in a case where an under layer of the resin layer is formed of a first material and a second relationship between a thickness of a resin layer and a luminance in a case where an under layer of the resin layer is formed of a second material different from the first material.

10. The imprinting method according to claim 1, wherein the relationship includes a first relationship between a thickness of a resin layer and a luminance in a case where an illumination light used to capture the image has a first wavelength profile and a second relationship between a thickness of a resin layer and a luminance in a case where the illumination light used to capture the image has a second wavelength profile different from the first wavelength profile.

11. An imprinting apparatus comprising:
a resin fluid dispenser configured to supply resin fluid onto a substrate;
an imaging device configured to capture an image of a resin layer formed on a region of the substrate with the resin fluid supplied from the resin fluid dispenser; and
a control circuit configured to:
determine a luminance distribution in the region in the captured image;
determine a thickness distribution of the resin layer based on a relationship between a thickness of a resin layer and a luminance and the determined luminance distribution;
determine a resin fluid supply condition to form a resin layer in a predetermined thickness range, based on the determined thickness distribution; and
control the resin fluid dispenser to supply resin fluid in accordance with the determined resin fluid supply condition.

12. The imprinting apparatus according to claim 11, wherein the thickness distribution indicates a first subregion in the region of the first substrate having a first thickness and a second subregion in the region of the first substrate having a second thickness greater than the first thickness.

13. The imprinting apparatus according to claim 12, wherein the resin fluid supply condition includes a first drive voltage to be applied to the resin fluid dispenser when supplying the resin fluid onto a subregion corresponding to the first subregion and a second drive voltage to be applied to the resin fluid dispenser when supplying the resin fluid onto a subregion corresponding to the second subregion, the second drive voltage being greater than the first drive voltage.

14. The imprinting apparatus according to claim 12, wherein the resin fluid supply condition includes a first frequency of a first drive voltage to be applied to the resin fluid dispenser when supplying the resin fluid onto a subregion corresponding to the first subregion and a second frequency of a second drive voltage to be applied to the resin fluid dispenser when supplying the resin fluid onto a subregion corresponding to the second subregion, the second frequency being greater than the first frequency.

15. The imprinting apparatus according to claim 12, wherein the resin fluid supply condition includes a first speed of movement of the resin fluid dispenser when supplying the resin fluid onto a subregion corresponding to the first subregion and a second speed of the movement of the resin fluid dispenser when supplying the resin fluid onto a subregion corresponding to the second subregion, the second speed being less than the first speed, the movement of the resin fluid dispenser being along a substrate surface.

16. The imprinting apparatus according to claim 12, wherein the resin fluid supply condition includes a first amount of fluid resin supply per unit area when supplying the resin fluid onto a subregion corresponding to the first subregion and a second amount of fluid resin supply per the unit area when supplying the resin fluid onto a subregion corresponding to the second subregion, the second amount being greater than the first amount.

17. The imprinting apparatus according to claim 12, wherein the resin fluid supply condition includes a first fluid resin drop location when supplying the resin fluid onto a subregion corresponding to the first subregion and a second fluid resin drop location when supplying the resin fluid onto a subregion corresponding to the second subregion.

18. The imprinting apparatus according to claim 11, wherein the resin layer formed on the region of the first substrate is a solidified resin layer.

19. The imprinting apparatus according to claim 11, wherein the relationship includes a first relationship between a thickness of a resin layer and a luminance in a case where an under layer of the resin layer is formed of a first material and a second relationship between a thickness of a resin layer and a luminance in a case where an under layer of the resin layer is formed of a second material different from the first material.

20. The imprinting apparatus according to claim 11, wherein the relationship includes a first relationship between a thickness of a resin layer and a luminance in a case where an illumination light used to capture the image has a first wavelength profile and a second relationship between a thickness of a resin layer and a luminance in a case where the illumination light used to capture the image has a second wavelength profile different from the first wavelength profile.
